(19) United States
(12) Patent Application Publication
(10) Pub. No.: US 2021/0135044 A1
(43) Pub. Date: May 6, 2021

(54) MICRO-LED ARRAY TRANSFER METHOD, MANUFACTURING METHOD AND DISPLAY DEVICE

(71) Applicant: GOERTEK INC., Weifang City, Shandong (CN)

(72) Inventors: Quanbo ZOU, Weifang City, Shandong (CN); Xiaoyang ZHANG, Weifang City, Shandong (CN); Peixuan CHEN, Weifang City, Shandong (CN); Xiangxu FENG, Weifang City, Shandong (CN); Tao GAN, Weifang City, Shandong (CN); Zhe WANG, Weifang City, Shandong (CN)

(21) Appl. No.: 16/605,081

(22) PCT Filed: Apr. 19, 2017
(86) PCT No.: PCT/CN2017/081063

§ 371 Date: Oct. 14, 2019

(51) Int. Cl. H01L 33/00; H01L 25/075

(52) U.S. Cl. CPC H01L 33/0093; H01L 25/0753

(57) ABSTRACT

It is disclosed a micro-LED transfer method, manufacturing method and display device. The method for transferring a micro-LED array comprises: patterning conductive resist on a receiving substrate to cover electrodes for the micro-LED array to be transferred; bonding the micro-LED array on a first substrate with the receiving substrate through the conductive resist, wherein the first substrate is laser transparent; irradiating laser onto the micro-LED array from a side of the first substrate to lift-off the micro-LED array from the first substrate. According to an embodiment, the performance of a micro-LED device may be improved.

### FIELD OF THE INVENTION

The present invention relates to a method for transferring a micro-LED array, a method for manufacturing a display device and a display device.

### BACKGROUND OF THE INVENTION

The micro-LED technology refers to the LED array of small size integrated on a substrate with high density. Currently, the micro-LED technology is starting development, and it is expected in the industry that a high-quality micro-LED product comes into the market. High-quality micro-LED will have a deep affection on the conventional display products such as LCD/OLED that have already been put into the market.

In the process of manufacturing micro-LEDs, a micro-LED array is first formed on a growth substrate. Then, the micro-LED array is transferred to a receiving substrate, or is transferred to a receiving substrate via a carrier substrate. The receiving substrate is a display screen, for example.

In the prior art, the micro-LED array can be transferred from one substrate to another substrate through laser lifting-off (LLO).

FIG. 1 shows a prior art example of transferring a micro-LED array from a first substrate 101 (a carrier substrate or a growth substrate) to a receiving substrate 102. As shown in FIG. 1, the micro-LED array 104 is formed on the first substrate 101. The micro-LED array 104 is bonded onto the receiving substrate 102. For example, the micro-LED array 104 is bonded onto the anode 106 on top of a TFT (Thin Film Transistor) circuitry 103 formed in the receiving substrate 102 through solder bond 105. The first substrate 101 is laser-transparent. Laser 107 is irradiated from the side of the first substrate 101 onto the micro-LED array 104 to lift-off it.

Since the micro-LEDs in the micro-LED array are of a very small size, the bonding strength between the micro-LEDs and the receiving substrate is very low. Especially, when the resolution of the display device is improved and the micro-LEDs are getting smaller and smaller, the yield loss during transfer is increased.

The bonding strength can be improved when the bonding temperature is elevated. However, the elevated bonding temperature will significantly degrade the bonding quality due to thermal mismatch of the micro-LEDs and the receiving substrate. In this regard, lowered bonding temperature is preferred, especially, for a micro-LED transfer with a large area, where the bonding strength will be a key concern.

Therefore, there is a demand in the art that a new solution for transferring a micro-LED array shall be proposed to address at least one of the problems in the prior art.

### SUMMARY OF THE INVENTION

One object of this invention is to provide a new technical solution for transferring a micro-LED array.

According to a first aspect of the present invention, there is provided a method for transferring a micro-LED array, comprising: patterning conductive resist on a receiving substrate to cover electrodes for the micro-LED array to be transferred; bonding the micro-LED array on a first substrate with the receiving substrate through the conductive resist, wherein the first substrate is laser transparent; irradiating laser onto the micro-LED array from a side of the first substrate to lift-off the micro-LED array from the first substrate.

Alternatively or optionally, the method further comprises: cross-linking or curing the conductive resist after the micro-LED array is bonded with the receiving substrate and before the micro-LED array is lifted-off.

Alternatively or optionally, the conductive resist is cross-linked or cured at a temperature lower than 200° C.

Alternatively or optionally, the conductive resist is photo resist and includes at least one of GCM3060, carbon-particle-filled resist or epoxy, and metal-particle-filled resist or epoxy. Alternatively or optionally, the specific contact conductivity of the conductive resist is larger than 1 S·cm2.

Alternatively or optionally, the micro-LED array is bonded with the receiving substrate at a temperature in a range of 50˜150° C.

Alternatively or optionally, a patterned area of the conductive resist is larger than that of a corresponding electrode.

Alternatively or optionally, the conductive resist is photo-definable.

According to a second aspect of the present invention, there is provided a method for manufacturing a display device, comprising transferring a micro-LED array from a first substrate to a receiving substrate of the display device by using the method for transferring a micro-LED array according to any embodiment.

According to a third aspect of the present invention, there is provided a display device manufactured by using the method for manufacturing a display device according to any embodiment.

According to an embodiment, the performance of a micro-LED device may be improved.

Further features of the present invention and advantages thereof will become apparent from the following detailed description of exemplary embodiments according to the present invention with reference to the attached drawings.

### BRIEF DESCRIPTION OF THE DRAWINGS

The accompanying drawings, which are incorporated in and constitute a part of the specification, illustrate embodiments of the invention and, together with the description thereof, serve to explain the principles of the invention.

FIG. 1 shows a schematic diagram of a prior art example of transferring a micro-LED array through laser lifting-off.

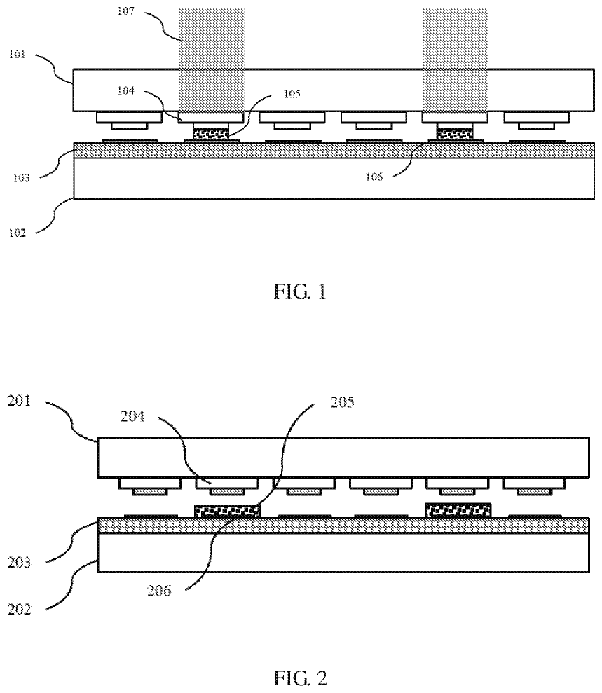

FIGS. 2-5 shows a schematic diagram of a process of transferring a micro-LED array from a first substrate to a receiving substrate according to an embodiment.

### DETAILED DESCRIPTION OF THE EMBODIMENTS

Various exemplary embodiments of the present invention will now be described in detail with reference to the drawings. It should be noted that the relative arrangement of the components and steps, the numerical expressions, and numerical values set forth in these embodiments do not limit the scope of the present invention unless it is specifically stated otherwise.

The following description of at least one exemplary embodiment is merely illustrative in nature and is in no way intended to limit the invention, its application, or uses.

Techniques, methods and apparatus as known by one of ordinary skill in the relevant art may not be discussed in detail but are intended to be part of the specification where appropriate.

In all of the examples illustrated and discussed herein, any specific values should be interpreted to be illustrative only and non-limiting. Thus, other examples of the exemplary embodiments could have different values.

Notice that similar reference numerals and letters refer to similar items in the following figures, and thus once an item is defined in one figure, it is possible that it need not be further discussed for following figures.

In an embodiment, it is proposed to use conductive resist as bonding material during a transfer of a micro-LED array.

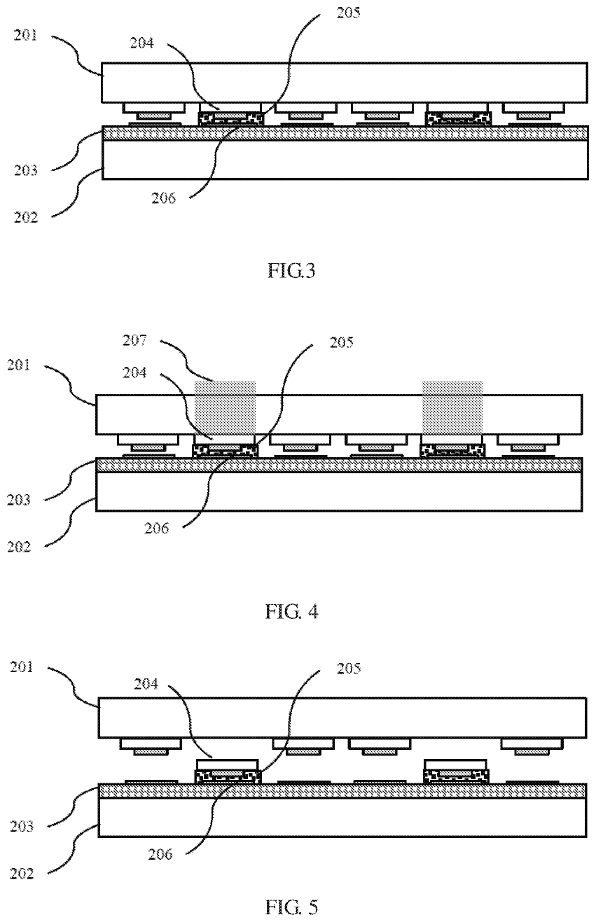

FIGS. 2-5 shows a schematic diagram of a process of transferring a micro-LED array from a first substrate to a receiving substrate according to an embodiment.

As shown in FIG. 2, conductive resist 205 is applied on a receiving substrate 202 and is patterned to cover electrodes 206 for the micro-LED array 204 to be transferred.

For example, the micro-LED array 204 is formed on a first substrate 201. The first substrate 201 is a growth substrate or a carrier substrate, and is laser transparent. For example, a TFT (Thin Film Transistor) circuitry 203 is formed in the receiving substrate 202, and the electrodes 206 are connected to the TFT circuitry 203.

For example, the conductive resist 205 is photo resist. It can include at least one of GCM3060 (SU8 type conductive photo-epoxy), carbon-particle-filled resist or epoxy, and metal-particle-filled resist or epoxy. For example, the specific contact conductivity of the conductive resist is larger than 1 S·cm², and preferably, larger than 10 S·cm². Optionally, a specific contact resistivity of the conductive resist is 1×10−3˜1×10−1 ohm·cm², and the resistance for a 10 μm square electrode is about 1-100 kohms. The conductive resist is electrically conductive for interconnection between electrodes on the receiving substrate and a p-metal of a micro-LED in the micro-LED array, for example.

In an example, a patterned area of the conductive resist 205 is larger than that of a corresponding electrode 206. For example, as shown in FIG. 2, the conductive resist 205 fully covers the electrode 206. In this manner, the bonding strength between a micro-LED of the array and a corresponding electrode will be improved. The yield loss during transfer can be decreased.

For example, the conductive resist is photo-definable. The conductive resist on the receiving substrate can be patterned through photolithography.

As shown in FIG. 3, the micro-LED array 205 on the first substrate 201 is bonded with the receiving substrate 202 through the conductive resist 205. The micro-LED array 205 may firstly be aligned with the electrodes 206 on the receiving substrate 202. The first substrate 201 may just include the micro-LED array or include several micro-LED arrays, such as red, green and blue micro-LED arrays, which will be transferred to the receiving substrate.

Since the conductive resist 205 fully covers the electrode 206, the contact area for bonding a micro-LED is increased and bonding strength is increased. In this manner, a performance of the micro-LED array during a transfer will be improved. In this embodiment, a robust bonding strength can be achieved by enlarged resist patterns hence. Here, more bonding surface between a micro-LED 204 and the receiving substrate 202 is obtained

In an example, the micro-LED array 205 is bonded with the receiving substrate 202 at a temperature in a range of 50˜150° C. This temperature is relatively close to a room temperature. This temperature is preferable for bonding substrates of different coefficient of thermal expansion (CTE). The thermal mismatch of the micro-LEDs and the receiving substrate will be lowered at such a temperature range. This approach will decease the thermal mismatch while providing a relatively strong bonding strength.

The bonding of the micro-LED 205 with the receiving substrate 202 is performed prior to a resist hard baking or exposure. The conductive resist 205 is soft and/or compressible during the bonding.

As shown in FIG. 4, laser 207 is irradiated onto the micro-LED array 205 from a side of the first substrate 201 to lift-off the micro-LED array 205 from the first substrate 201.

For example, the conductive resist 205 can be cross-linked or cured after the micro-LED array is bonded with the receiving substrate and before the micro-LED array is lifted-off. The cross-linking or curing can be performed by light exposure or elevating temperature. In this approach, the bonding strength during a transfer will be increased. For example, the conductive resist is cross-linked or cured at a temperature lower than 200° C.; preferably lower than 1° C.; further preferably, lower than 100° C.; and even further preferable, lower than 50° C.

As shown in FIG. 5, the micro-LED array 204 is separated from the first substrate 201 and is transferred onto the receiving substrate 202.

In a case where several micro-LED arrays, such as red, blue and green micro-LED arrays, are to be transferred to a receiving substrate, the above processes may be repeated.

In another embodiment, an embodiment includes a method for manufacturing a display device. The manufacturing method comprises transferring a micro-LED array from a first substrate to a receiving substrate of the display device by using the method for transferring a micro-LED array according to an embodiment as above. The display device can be a display panel, a display screen and so on.

In another embodiment, another embodiment includes a display device manufactured by using the method for manufacturing a display device according to an embodiment as above.

In another embodiment, another embodiment can further include an electronic apparatus. The electronic apparatus contains a display device as above. For example, the electronic apparatus can be a mobile phone, a pad computer and so on.

Although some specific embodiments of the present invention have been demonstrated in detail with examples, it should be understood by a person skilled in the art that the above examples are only intended to be illustrative but not to limit the scope of the present invention.

1. A method for transferring a micro-LED array, comprising:
patterning conductive resist on a receiving substrate to cover electrodes for the micro-LED array to be transferred;
bonding the micro-LED array on a first substrate with the receiving substrate through the conductive resist, wherein the first substrate is laser transparent;
irradiating laser onto the micro-LED array from a side of the first substrate to lift-off the micro-LED array from the first substrate.

2. The method according to claim 1, further comprising:
cross-linking or curing the conductive resist after the micro-LED array is bonded with the receiving substrate and before the micro-LED array is lifted-off.

3. The method according to claim 2, wherein the conductive resist is cross-linked or cured at a temperature lower than 200° C.

4. The method according to claim 1, wherein the conductive resist is photo resist and includes at least one of GCM3060, carbon-particle-filled resist or epoxy, and metal-particle-filled resist or epoxy.

5. The method according to claim 1, wherein the specific contact conductivity of the conductive resist is larger than 1 S·cm².

6. The method according to claim 1, wherein the micro-LED array is bonded with the receiving substrate at a temperature in a range of 50-150° C.

7. The method according to claim 1, wherein a patterned area of the conductive resist is larger than that of a corresponding electrode.

8. The method according to claim 1, wherein the conductive resist is photo-definable.

9. A method for manufacturing a display device, comprising transferring a micro-LED array from a first substrate to a receiving substrate of the display device by using the method for transferring a micro-LED array according to claim 1.

10. A display device manufactured by using the method for manufacturing a display device according to claim 9.
